(19) United States
(12) Patent Application Publication
(10) Pub. No.: US 2025/0021007 A1
(43) Pub. Date: Jan. 16, 2025

(54) PHOTORESIST DEVELOPER SOLUTIONS CONTAINING LOW FOAM DISPERSING COMPOSITIONS AND QUANTIFICATION METHODS

(71) Applicants: Yu Kang NIEH, Taoyuan (TW); Heng Chuan CHENG, Taoyuan (TW)

(72) Inventors: Yu Kang NIEH, Taoyuan (TW); Heng Chuan CHENG, Taoyuan (TW)

(21) Appl. No.: 18/221,889

(22) Filed: Jul. 14, 2023

(51) Int. Cl. G03F 7/32

(52) U.S. Cl. CPC G03F 7/322

(57) ABSTRACT

A qualification method for determining a dump time interval using a photoresist developer solution in a batch photoresist development includes: developing a substrate with the photoresist developer solution; determining whether a change of an absolute zeta potential value between the photoresist developer solution and a used photoresist developer solution exceeds a first specified limit; and determining whether a change in a particle size distribution between the photoresist developer solution and the used photoresist developer solution exceeds a second specified limit; wherein if the change of the absolute zeta potential value is above the first specified limit, dumping the used photoresist developer solution; and if the change in the particle size distribution is above the second specified limit, dumping the used photoresist developer solution.

### FIELD OF THE DISCLOSURE

This invention relates to photoresist developer solutions comprising dispersing compositions for solutions life extension and an efficient method to quantify the working life of the solutions, which can save chemicals use and, more importantly, process water use, potentially decreasing carbon emissions. The invention applies to any standard photoresist development process, preferably usable for PCBs, Soldermasks, flat panel displays, IC, etc.

### BACKGROUND OF THE DISCLOSURE

Photoresist materials are commonly used as coating masks to fabricate PCBs, Soldermasks, flat panel displays, and IC substrates. During the fabrication process, photoresist materials are applied to a substrate surface, such as copper, ITO (indium-tin oxide), silicon wafers, and other materials. The photoresist-coated substrate is exposed to radiation, generally UV, X-ray, or electric beam. After substrate exposure, it is sent to a photoresist development process, leaving a defined pattern of photoresist materials on its surface for further processing. After further processing, such as rinsing and etching, the photoresist materials are stripped from the substrate, and the defined pattern is accomplished.

A photoresist development, a significant process unit after photoresist exposure, is executed to leave behind the correctly defined pattern on a substrate surface. The photoresist left on the substrate after development will serve as a physical mask covering areas that need to be protected from chemical reactions during subsequent etching, implantation, lift-off, and the like. The development process is executed either via immersion development, spray development, or puddle developing, or the like. No matter what process the engineer uses, it should always go through rinsing and drying to ensure that the development activities will not continue after the developer has been removed from the substrate surface. The process subsequently removes unprotected parts of the photoresist materials, which will be dissolved or suspended in the photoresist developer solutions, where the unprotected parts of the resist polymers and other rinsed chemicals or materials are gradually accumulated in the used developer solutions.

High-resolution photoresists are particularly employed in micro-electronics and micro-systems technology before, and now as technology becomes more advanced, and integrated, and requirements for gradually narrower line width/line space (L/S), their demands are growing (e.g., refer to Taiwan Publication No. 1475318B). There are several types of photoresists comprising various chemical structures and compositions. For positive photoresists, they are mainly composed of film formers like phenolic novolac and cresol novolac and photosensitive components like naphthoquinone diazide in solvents like propylene glycol methyl ether acetate (PMAc). And for negative photoresists, the resins such as acrylic-based polymers and acidifier compounds are dissolved in suitable organic solvents. There are also photoresist materials that function as protective coatings, like PMMA which are used for the etching process and prevent the destruction of substrates. Highly working temperature-positive resins based on polyimide are also seen in the niche development process. Generally, the resistance may be a dry film photoresist or a liquid formulation photoresist. Photoresist materials may be applied by any standard process, including coating, cold or hot lamination, spin coating, roller coating, and so forth, onto the substrate. After curing the applied resist, the substrate is exposed to imaging radiation to differentiate between the image and non-image areas.

To fulfill the spirit of sustainability, while maintaining the excellent quality of products, it is necessary to fabricate the defined substrate with reduced chemical use, reduced chemical waste, and, most importantly, the utilization of process water. Beneficially, taking advantage of process water saving, carbon emission saving can furthermore be calculated. Workers must think of new and environmentally friendly chemical development processes. Ideally, developer solutions are one of the strategic ways to maximize the recycling of process water or said photoresist. Nevertheless, it's a challenge to implement the idea in practice. One of the most critical obstacles is insufficient photoresist materials information. The choice of photoresist materials used in the defined substrate development process depends on various process conditions and manufacturing requirements, such as defined etching thickness, post-process objectives, mask pattern resolution allowance, and sometimes materials cost. Photoresist materials' suppliers have detailed composition know-how that can't be disclosed: hence it's difficult for development process engineers or quality control representatives to get sufficient photoresist materials composition information. After the development process, the unwanted part of photoresist residuals must be removed to allow further processing. Without sufficient information on parts of photoresists chemical compositions, it is difficult to determine how much time interval process water or said photoresist developer solutions can be recycled and reused while keeping their development performance the same. Insufficient information on parts of photoresist materials compositions makes developing chemical solutions design more complicated or, to go a step further, very difficult for process engineers to optimize recycled developer solutions working lifetime. Hence, it's critical objective to resolve the challenge.

Taking negative dry film photoresist application as an illustration, after radiation exposure, the exposed areas of the resist materials are hardened: hence these areas can't be attacked by developing solutions, whereas the unexposed areas are soluble and can be washed off via alkaline developer solutions. The chemical developer solutions are typically alkaline solutions based on compositions of water, tetra-methyl ammonium hydroxide (TMAH), tetra-butyl ammonium hydroxide (TBAH), potassium carbonates, sodium carbonates, ammonium carbonates, and above mixture formulations together with some organic solvents such as ethylene glycols, ethylene glycol mono-butyl ether, diethylene glycol mono-butyl ether, tri-ethylene glycol mono-butyl ether, propylene glycol monomethyl ether, and other chemicals. The normal working temperature ranges from 20 to 40° C., and under this circumstance, the normal working pH value intervals of this solution are about 10.0 to 12.0. Too high pH leads to bulk stripping of the photoresist; on the other hand, too low pH is ineffective in the developing process. Generally, the concentration of pure carbonate in the photoresist developer process is controlled at 1.0 wt % as a standard, with a range of around 0.7 wt %˜1.5 wt %. In addition to the abovementioned compositions used as developers, some phosphates, borates, hydroxides, amine-salts, and non-alkali metals salts are applied as pH regulators to inhibit chemical attack on processing target substrates like silicon or corrosion-sensitive metal layers. Typically, the pH demand of the chemical development unit ranges optimally from 10.2 to 11.2. Development solutions are normally distributed through a spraying machine with short working times. The solutions are sent to recycle line bath and reused until the solutions' developing capability decreases to a non-effective level. However, as previously mentioned, it's far more difficult to determine a non-effective level under insufficient photoresist materials' composition information. In general, to keep the chemical development process from being not interrupted, workers are requested to dump developing solutions at regular time intervals. They are dumped according to plant history operating experience but most often dumped every labor shift even though the developing solutions are still active because of risk management of shutdown prevention. However, this risk-taking action demands much water utilization, potentially causing more carbon emissions from the wastewater treatment units. As technology becomes more integrated such as Substrate-Like PCB (SLP) requiring essentially narrower L/S buildup, the above-mentioned situation is becoming a big challenge.

In the application of PCB manufacturing, U.S. Pat. No. 5,853,963 provides a method to maintain the activity of aqueous carbonate-based photoresist solutions by controlled additions of aqueous hydroxide or hydroxide plus carbonate solutions to maintain a given pH or pH range. The prior art claimed the way for life expansion of the spent chemical developer solutions batch. Following recent technological development to encounter much more integrated circuits, only pH control becomes unreliable in the chemical development process. It's because typically alkaline solutions can't effectively penetrate into much narrower gap of unwanted photoresist polymers and chemically attack them well. To improve this, some ionic or non-ionic surfactants and dispersants are added in developing solutions to enhance the penetration ability to develop ions. Together with the ions, surfactants can form shelter space in aqueous solutions to cover stripped photoresist materials and residual chemicals, distinguishing from water. It may be viewed as concentrated Oil in Water (O/W) suspension. Ideally, adding surfactant is workable for developing performance improvement. Nevertheless, since recycle of developer solutions are necessary, workers may encounter two obstacles:
I. Adduct of surfactants further generate foaming phenomena on the air-solution interface of the developer process tank, which may cause effluent or outflow of solutions. Non-stop growing foam will lead to tank machine unit shutdown.
II. Once fresh developer solutions are recycled to be spent, the batch starts accumulating unwanted photoresist materials and other residual chemicals. It gradually transforms from clear liquid to non-transparent suspension, bringing unwanted resists and residuals. While the suspension is too concentrated to dissolve residual materials, the rest of the stripped materials or chemicals start aggregating and potentially adsorb to any solid boundaries of the developing solution tank machines like recycle pump, recycle pipe, spraying line, and tank walls. More dangerously, these aggregating materials (dirt colloids) may absorb back into the processing target substrate. These unwanted back adsorptions may lead to substrate development failure.

These two obstacles usually occur at the same time. For obstacle I, adding de-foamers and via control of developer solution tank pH may be used to manage the problem. However, it's surprising to find that inappropriate adduct of de-foamers will adversely promote dirt colloid aggregation and hereinafter contaminate any solid boundaries of the developer solution tank. Production is then interrupted, and workers need to spend more time cleaning dirt, standing that more water utilization and other cleaning chemicals are needed, which likely conflict with the spirit of sustainability.

Furthermore, it has been a long time for workers to develop processes using operation experience to judge and determine the dump time of developing solutions tanks. Usually. they are regularly dumped every labor shift for 8 hrs. Honestly, there still needs to be effective able-to-quantified methods to identify whether the developing solutions are completely exhausted to ensure uninterrupted production or to determine the appropriately optimized dumping time of every fresh batch developing solution. In the past, for example, PCBs with a negative type of photoresist may have 40˜60% of the photoresist in the cross-linked or insoluble state, leaving the remainder to be dissolved in the developer solution. Nowadays, for much more integrated substrates, above 60% of the remainder photoresist may occur, balancing between dump time intervals (prolonging developing solutions' operating life) while keeping stable developing activities becomes an urgent and essential task force.

It is an objective of the present invention to provide dispersing compositions applied in photoresist developing process and method to quantify their lifetime extension. The innovative compositions can significantly extend the aqueous-based developer solutions working life even though they already contain unwanted photoresist materials and other residual chemicals. The quantification method mentioning suspending colloids zeta potential distribution and particle size distribution of the suspensions can effectively determine the dump time intervals of developer solution tanks in practical applications. The invention points out an innovative way with reduced chemical use, chemical waste, and utilization of process water, thus potentially decreasing carbon emissions.

All referenced patents, applications and literature are incorporated herein by reference in their entirety. Furthermore, where a definition or use of a term in a reference, which is incorporated by reference herein, is inconsistent or contrary to the definition of that term provided herein, the definition of that term provided herein applies and the definition of that term in the reference does not apply. The disclosed embodiments may seek to satisfy one or more of the above-mentioned desires. Although the present embodiments may obviate one or more of the above-mentioned desires, it should be understood that some aspects of the embodiments might not necessarily obviate them.

### BRIEF SUMMARY OF THE DISCLOSURE

In a general implementation, an aspect of the embodiment is directed to a qualification method for determining a dump time interval using a photoresist developer solution in a batch photoresist development, comprising:
developing a substrate with the photoresist developer solution;
determining whether a change of an absolute zeta potential value between the photoresist developer solution and a used photoresist developer solution exceeds a first specified limit; and
determining whether a change in a particle size distribution between the photoresist developer solution and the used photoresist developer solution exceeds a second specified limit; wherein
if the change of the absolute zeta potential value is above the first specified limit, dumping the used photoresist developer solution; and
if the change in the particle size distribution is above the second specified limit, dumping the used photoresist developer solution.

In another aspect combinable with the general implementation, the first specified limit is above 9%.

Among the many possible implementations of the qualification method, the second specified limit is above 20%.

Further, it is contemplated that the photoresist developer solution comprises:
0 wt %˜99.5 wt % Water;
0.5 wt %˜1.5 wt % Alkaline chemical mixtures comprising tetra-methyl ammonium hydroxide, tetra-butyl ammonium hydroxide, potassium carbonates, sodium carbonates, and ammonium carbonates;
0.001 wt %˜0.5 wt % dispersing agents;
0.001 wt %˜0.5 wt % wetting agents;
0.001 wt %˜0.5 wt % antifoaming agents; and
0.001 wt %˜0.5 wt % de-foaming agents.

In the alternative, the qualification method may further comprise a step of:
calculating the change of the absolute zeta potential value by a first zeta potential value and a first signal peak intensity measuring from the photoresist developer solution, and a second zeta potential value and a second signal peak intensity measuring from the used photoresist developer solution.

It is still further contemplated that the qualification method may further comprise a step of:
calculating the change of the particle size distribution by a first particle size distribution and a first signal peak intensity measuring from the photoresist developer solution, and a second particle size distribution and a second signal peak intensity measuring from the used photoresist developer solution.

Another aspect of the embodiment, the qualification method may further comprise a step of:
recycling the used photoresist developer solution to a next batch photoresist development.

In another aspect combinable with the general implementation, the qualification method may further comprise a step of:
determining whether a second particle size distribution measuring from the used photoresist developer solution becomes more than one particle size distribution;
shutting down the batch photoresist development.

In another aspect combinable with the general implementation, the qualification method may further comprise a step of:
acquiring a first signal peak intensity of the photoresist developer solution and a second signal peak intensity of the used photoresist developer solution, using the zeta potential and particle size analyzer.

In another aspect combinable with the general implementation, the first signal peak intensity and the second signal peak intensity range from +30 to −270 mV.

In another aspect combinable with the general implementation, the qualification method may further comprise a step of:
acquiring a first zeta potential value of the photoresist developer solution and a second zeta potential value of the used photoresist developer solution, using a zeta potential and particle size analyzer.

In another aspect combinable with the general implementation, the qualification method may further comprise a step of:
acquiring a first particle size distribution of the photoresist developer solution and a second particle size distribution of the used photoresist developer solution, using a zeta potential and particle size analyzer.

Accordingly, the present disclosure is directed to a photoresist developer solution, wherein the dispersing agents comprise carbon-carbon triple bond with hydrophilic-lipophilic balance (HLB) values ranging from 4 to 18.

In a general implementation, the dispersing agents comprise carbon-carbon double bond having aromatic structures with hydrophilic-lipophilic balance (HLB) values ranging from 3 to 18.

In another aspect combinable with the general implementation, the wetting agents are selected from a group consisting of mono-ethylene glycol, di-ethylene glycol, tri-ethylene glycol, polyethylene glycol with molecular weight from 100 to 600, ethoxylated butyl ethers, ethylene carbonate, propylene carbonate, C8-10 fatty alcohol 2-3 moles ethylene oxide (EO) ethoxylates, non-ionic chemicals comprising below 11 carbon chains, ethylene oxide adducts with HLB ranging from 4 to 10, propylene oxide adducts with HLB ranging from 4 to 10, linear secondary alcohol ethoxylates with HLB ranging from 4 to 10, linear secondary alcohol proxylates with HLB ranging from 4 to 10, branched secondary alcohol ethoxylates with HLB ranging from 4 to 10, branched secondary alcohol proxylates with HLB ranging from 4 to 10 and a combination thereof.

In another aspect combinable with the general implementation, the antifoaming agents are selected from a group consisting of primary linear C12-14 fatty alcohol 2-3 moles ethylene oxide (EO) ethoxylates, isotridecanol 2-3 moles EO ethoxylates, isodecyl alcohol 2-3 moles EO ethoxylates, oleyl alcohol 2-3 moles EO ethoxylates, C16-18 fatty alcohol 2-3 moles ethylene oxide (EO) ethoxylates, triblock copolymers of ethylene oxide and propylene oxide, C8-14 alcohol ethylene oxide/propylene oxide block copolymers, C8-14 alcohol ethylene oxide/propylene oxide random copolymers, primary linear C12-14 fatty alcohol ethylene oxide/propylene oxide block copolymers, primary linear C12-14 fatty alcohol ethylene oxide/propylene oxide random copolymers, isotridecanol ethylene oxide/propylene oxide block copolymers, iso-tridecanol ethylene oxide/propylene oxide random copolymers, oleyl alcohol ethylene oxide/propylene oxide block copolymers, oleyl alcohol ethylene oxide propylene oxide random copolymers, C16-18 fatty alcohol ethylene oxide/propylene oxide block copolymers, polypropylene glycols with molecular weight up to 2000 and a combination thereof.

In another aspect combinable with the general implementation, the de-foaming agents are selected from a group consisting of white mineral oil, palm kernel oil, palm sterin oil, horse oil, shea butter, wax, other mineral oil, and a combination thereof.

In another aspect combinable with the general implementation, the dispersing agents are selected from a group consisting of 2,4,7,9-Tetramethyl-5-decyne-4,7-diol ethoxylates with HLB values ranging from 4 to 18, 1,4-Butynediol ethoxylates with HLB value ranging from 4 to 18, 2,4,7,9-Tetramethyl-5-decyne-4,7-diol ethoxylates or proxylates with HLB value ranging from 4 to 18, 1,4-Butynediol ethoxylates or proxylates with HLB value ranging from 4 to 18 and a combination thereof.

In another aspect combinable with the general implementation, the dispersing agents are selected from a group consisting of bio-based Cardanol ethoxylates with HLB value ranging from 3 to 18, nonyl phenol ethoxylates with HLB value ranging from 3 to 18, alkyl phenol ethoxylates with HLB value ranging from 3 to 18 and a combination thereof.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above and below as acting in certain combinations and even initially claimed as such, one or more features from a claimed combination can in some cases be excised from the combination, and the claimed combination may be directed to a subcombination or variation of a subcombination.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims.

The details of one or more implementations of the subject matter described in this disclosure are set forth in the accompanying drawings and the description below. Other features, aspects, and advantages of the subject matter will become apparent from the description, the drawings, and the claims.

### BRIEF DESCRIPTION OF THE DRAWINGS

It should be noted that the drawing figures may be in simplified form and might not be too precise scale. In reference to the disclosure herein, for purposes of convenience and clarity only, directional terms such as top, bottom, left, right, up, down, over, above, below, beneath, rear, front, distal, and proximal are used with respect to the accompanying drawings. Such directional terms should not be construed to limit the scope of the embodiment in any manner.

FIG. 1 is a schematic view of a batch photoresist development according to an aspect of the embodiment.

FIG. 2 generally depicts a qualification method for determining the dump time intervals using the photoresist developer solution in the batch photoresist development according to an aspect of the embodiment.

FIG. 3 generally depicts a qualification method for determining the dump time intervals using the photoresist developer solution in the batch photoresist development according to an aspect of the embodiment.

FIG. 4 generally depicts a qualification method for determining the dump time intervals using the photoresist developer solution in the batch photoresist development according to an aspect of the embodiment.

FIG. 5 generally depicts a qualification method for determining the dump time intervals using the photoresist developer solution in the batch photoresist development according to an aspect of the embodiment.

FIG. 6 generally depicts compositions for the photoresist developer solution of a control group, Example I, and Example II for the batch photoresist development according to an aspect of the embodiment.

FIGS. 7A to 7C generally depict analytical results measured by an analytical instrument (a zeta potential and particle size analyzer) according to an aspect of the embodiments.

FIG. 8 generally depicts a change of the absolute zeta potential value for the control group, Example I, and Example II according to an aspect of the embodiments.

FIGS. 9A to 9F generally depict analytical results measured by the analytical instrument (a zeta potential and particle size analyzer) according to an aspect of the embodiments.

FIG. 10 generally depicts a change of the particle size distribution for the control group, Example I, and Example II according to an aspect of the embodiments.

FIG. 11 depicts a pattern change of the particle size distribution for the control group, Example I, and Example II according to an aspect of the embodiments.

FIG. 12 shows a condition of dirt colloids measured by visual confirmation according to an aspect of the embodiment.

### DETAILED DESCRIPTION OF THE EMBODIMENTS

The different aspects of the various embodiments can now be better understood by turning to the following detailed description of the embodiments, which are presented as illustrated examples of the embodiments defined in the claims. It is expressly understood that the embodiments as defined by the claims may be broader than the illustrated embodiments described below.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

It shall be understood that the term “means,” as used herein, shall be given its broadest possible interpretation in accordance with 35 U.S.C., Section 112(f). Accordingly, a claim incorporating the term “means” shall cover all structures, materials, or acts set forth herein, and all of the equivalents thereof. Further, the structures, materials or acts and the equivalents thereof shall include all those described in the summary of the invention, brief description of the drawings, detailed description, abstract, and claims themselves.

Unless defined otherwise, all technical and position terms used herein have the same meaning as commonly understood by one of ordinary skill in the art to which the invention pertains. Although many methods and materials similar, modified, or equivalent to those described herein can be used in the practice of the present invention without undue experimentation, the preferred materials and methods are described herein. In describing and claiming the present invention, the following terminology will be used in accordance with the definitions set out below.

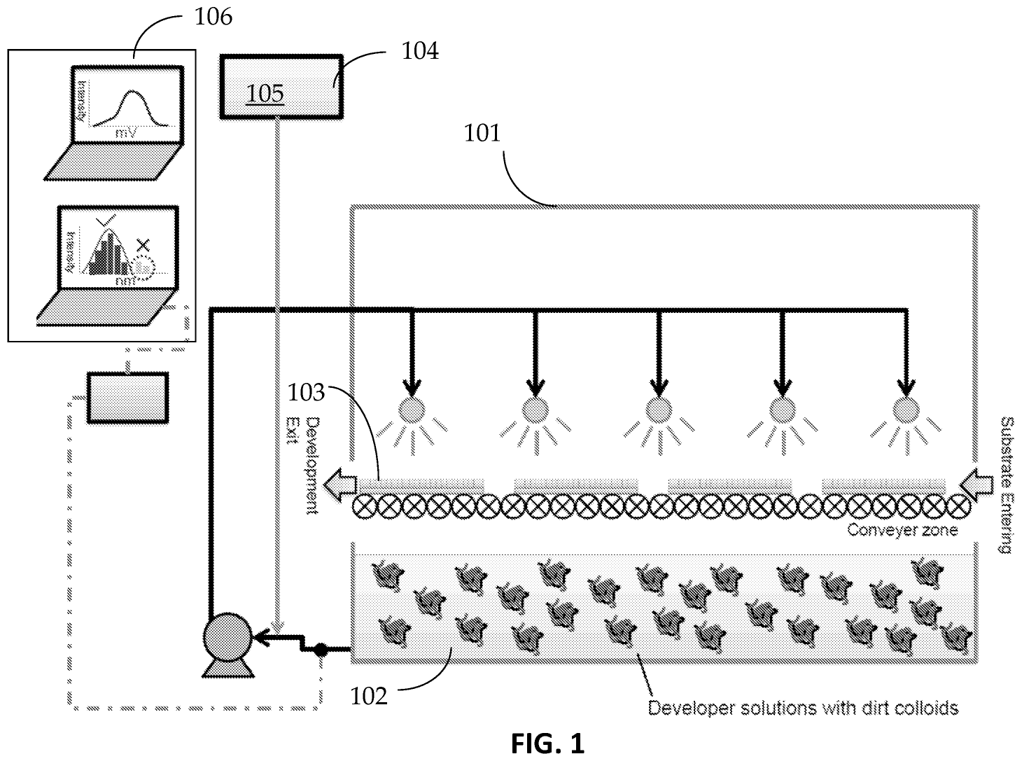

FIG. 1 generally depicts a schematic view of a batch photoresist development 100 according to an aspect of the embodiment.

Referring to FIG. 1, the batch photoresist development 100 may comprise a chemical developing process tank 101, a photoresist developer solution 105 containing low foam dispersing compositions, a plurality of subtracts 103 entering into the chemical developing process tank 101, and a corresponding quantification machine monitoring developed solutions/suspensions particle size distribution and suspending colloids zeta potential distribution, wherein the qualification machine may be utilized to determine dump time intervals of the chemical developing process tank.

In some embodiments, the batch photoresist development 100 may comprise a feed source 104 containing the photoresist developer solution 105, wherein the photoresist developer solution 105 may be filled into the chemical developing process tank 101.

Continuing to FIG. 1, when the photoresist developer solution 105 is applied in the batch photoresist development 100 (the substrate developing process), the photoresist developer solution starts washing off unwanted photoresist materials and aqueous solutions gradually to generate colloidal dirt suspensions. Once the photoresist developer solution is recycled and reused several times, the colloidal suspensions are transferred from dilute to concentrated ones. In addition to monitoring pH value or alkaline ions value in the chemical developing process tank 101, the key methodologies of the invention disclosure to quantify the stability of the colloidal suspensions and to effectively determine the dump time intervals of the chemical developing process tank is to online/off-line monitoring of suspensions particle size distribution and zeta potential of suspending colloids.

In some embodiment, an analytical instrument 106 (a zeta potential and particle size analyzer) may record one zeta potential value (a first zeta potential value) and one particle size distribution (a first particle size distribution) from the photoresist developer solution 105 as blank references. For each bath/batch of photoresist development, the analytical instrument 106 may also record one zeta potential value (a second zeta potential value) and one particle size distribution (a second particle size distribution) from the used photoresist developer solution 102. The records of the first particle size distribution and the first zeta potential value may be compared with the second zeta potential value and the second particle size distribution.

In some embodiments, two key indices to evaluate dumped timer intervals of the used photoresist developer solution are a change of an absolute zeta potential value between the photoresist developer solution and the used photoresist developer solution, and a change of the particle size distribution between the photoresist developer solution and the used photoresist developer solution.

In the photoresist developer solution, the relatively uniform and narrower particle size distribution together with zeta potential is set as a blank reference. When the photoresist developer solution is recycled and reused in more baths/batches (generally in terms of square feet of processed target substrates per gallon of the photoresist developer solution or process working hours), it can be checked to recycle the used photoresist developer solution/suspension with its particle size distribution of colloidal particles changing from narrower into border or even separated distributed. It should be noted that the corresponding zeta potential value of the used photoresist developer solution may gradually change, different from the photoresist developer solution.

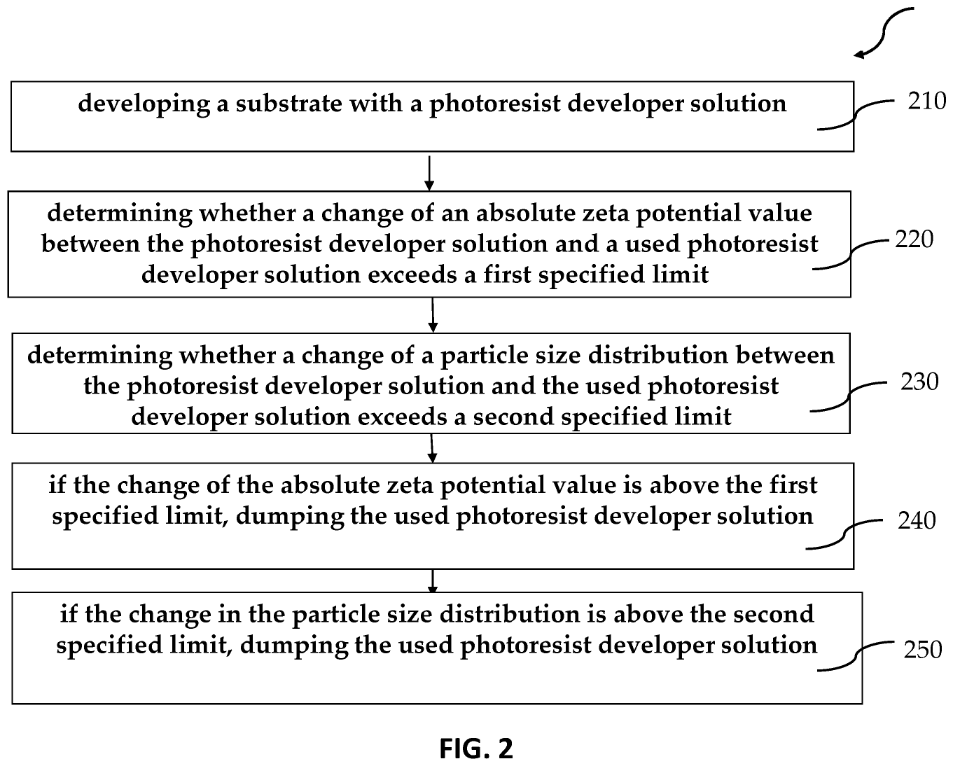

FIGS. 2-5 generally depict a qualification method 200 for determining the dump time intervals using the photoresist developer solution in the batch photoresist development according to an aspect of the embodiment.

Referring to FIG. 2, the qualification method for determining the dump time intervals using the photoresist developer solution in the batch photoresist development 200 may comprise steps of:
developing a substrate with the photoresist developer solution 210;
determining whether the change of the absolute zeta potential value between the photoresist developer solution and the used photoresist developer solution exceeds a first specified limit 220;
determining whether the change of the particle size distribution between the photoresist developer solution and the used photoresist developer solution exceeds a second specified limit 230;
if the change of the absolute zeta potential value is above the first specified limit, dumping the used photoresist developer solution 240; and
if the change in the particle size distribution is above the second specified limit, dumping the used photoresist developer solution 250.

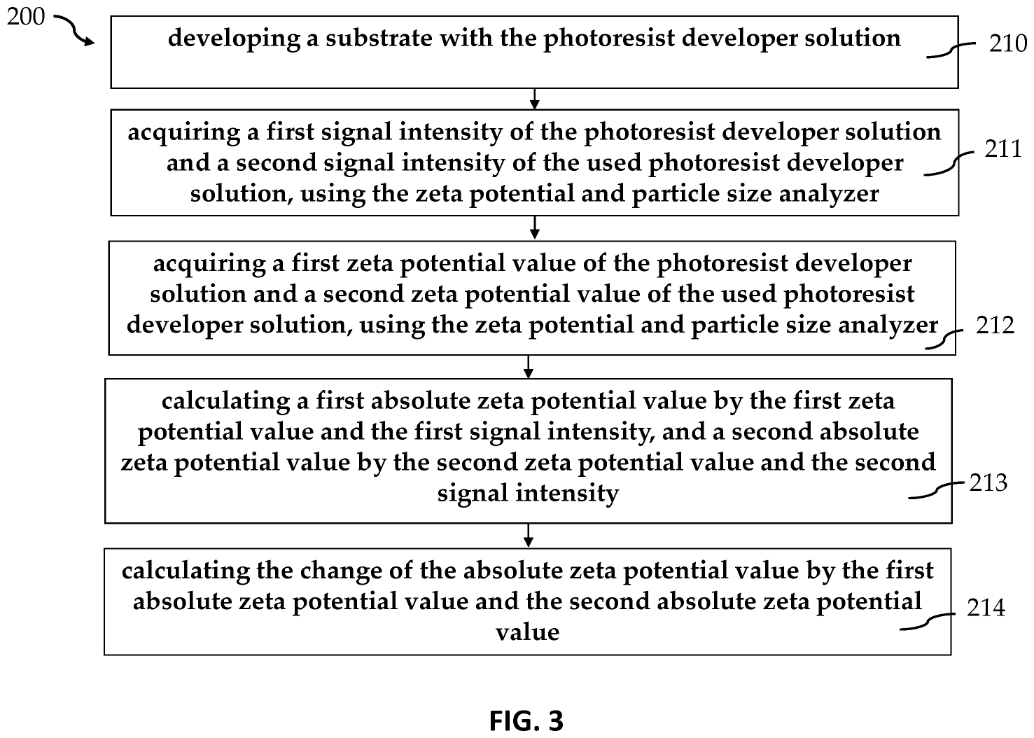

Referring to FIG. 3, in some embodiments, the qualification method 200 may further comprise a step of:
acquiring a first signal peak intensity of the photoresist developer solution and a second signal peak intensity of the used photoresist developer solution, using the zeta potential and particle size analyzer 211.

In still some embodiments, the qualification method 200 may further comprise a step of:
acquiring the first zeta potential value of the photoresist developer solution and the second zeta potential value of the used photoresist developer solution, using the zeta potential and particle size analyzer 212.

It should be noted that, in some embodiments, the first signal peak intensity, the second signal peak intensity, the first zeta potential value, and the second zeta potential value may be measured by the zeta potential and particle size analyzer.

It should be understood that the above-described zeta potential and particle size analyzer are exemplary and any other zeta potential and particle size analyzer can be adopted in various embodiments of this disclosure.

In some embodiments, the change of the absolute zeta potential value may be defined by a first absolute zeta potential value measuring from the photoresist developer solution and a second absolute zeta potential value measuring from the used photoresist developer solution, wherein the first absolute zeta potential value may be defined by the following equation:
First absolute zeta potential value=absolute value of (the integration of first signal peak intensity area with respect to specified range of zeta potential value)

The second absolute zeta potential value may be defined by the following equation:
Second absolute zeta potential value=absolute value of (the integration of second signal peak intensity area with respect to specified range of zeta potential value)

In some embodiments, the first signal peak intensity area may be defined by a first signal peak intensity with respect to specified range of zeta potential value. In still some embodiments, the second signal peak intensity area may be defined by a second signal peak intensity with respect to specified range of zeta potential value.

Accordingly, the change of the absolute zeta potential value may be calculated by the following equation:
[(second absolute zeta potential value−first absolute zeta potential value)/first zeta potential value]*100%

In still some embodiments, the qualification method 200 may further comprise a step of:
calculating the first absolute zeta potential value by the first zeta potential value and the first signal peak intensity measuring from the photoresist developer solution, and the second absolute zeta potential value by the second zeta potential value and the second signal peak intensity measuring from the used photoresist developer solution 213.

Continuing with FIG. 3, in some embodiments, the qualification method 200 may further comprise a step of:
calculating the change of the absolute zeta potential value by the first absolute zeta potential value and the second absolute zeta potential value 214.

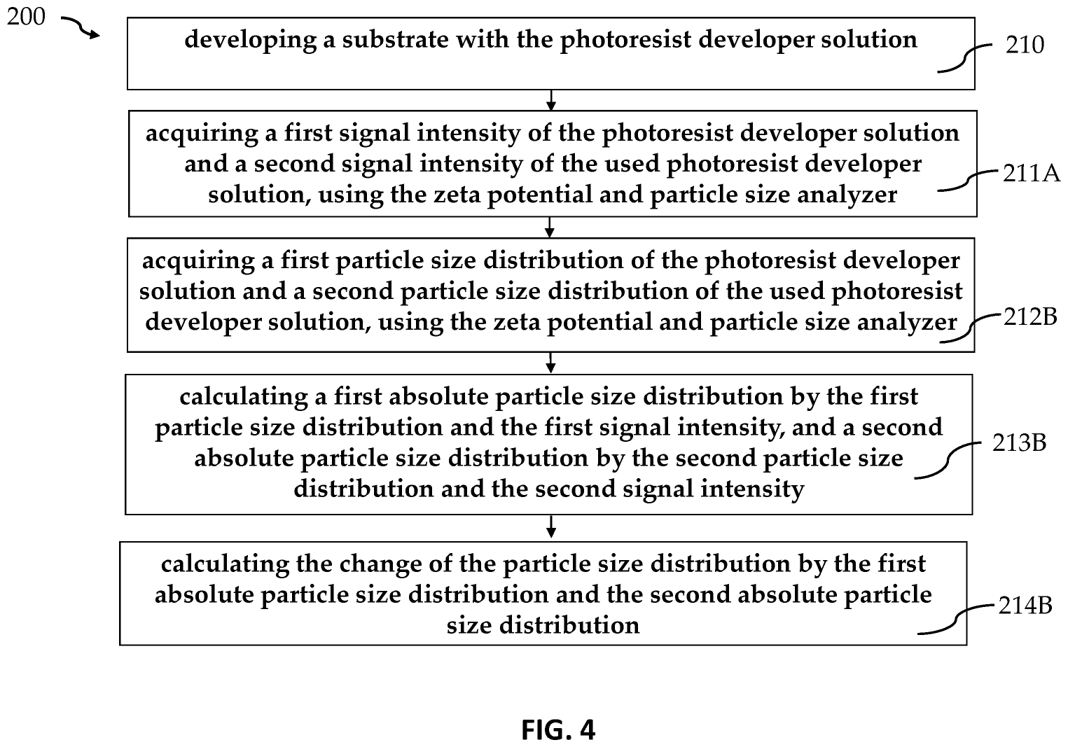

Referring to FIG. 4, in some embodiments, the qualification method 200 may further comprise a step of:
acquiring the first signal peak intensity of the photoresist developer solution and the second signal peak intensity of the used photoresist developer solution, using the zeta potential and particle size analyzer 211A.

In still some embodiments, the qualification method 200 may further comprise a step of:
acquiring the first particle size distribution of the photoresist developer solution and the second particle size distribution of the used photoresist developer solution, using a zeta potential and particle size analyzer 212B.

It should be noted that, in some embodiments, the first signal peak intensity, the second signal peak intensity, the first particle size distribution, and the second particle size distribution may be measured by the zeta potential and particle size analyzer.

It should be understood that the above-described zeta potential and particle size analyzer are exemplary and any other zeta potential and particle size analyzer can be adopted in various embodiments of this disclosure.

In some embodiments, the change of the particle size distribution may be defined by a first absolute particle size distribution measuring from the photoresist developer solution and a second absolute particle size distribution measuring from the used photoresist developer solution, wherein the first absolute particle size distribution may be defined by the following equation:
First absolute particle size distribution=absolute value of (the integration of first signal peak intensity area with respect to specified range of particle size distribution)

The second absolute particle size distribution may be defined by the following equation:
Second absolute particle size distribution=absolute value of (the integration of second signal peak intensity area with respect to specified range of particle size distribution) In some embodiments, the first signal peak intensity area may be defined by a first signal peak intensity with respect to specified range of particle size distribution. In still some embodiments, the second signal peak intensity area may be defined by a second signal peak intensity with respect to specified range of particle size distribution.

Accordingly, the change of the particle size distribution may be calculated by the following equation:

$$[ ( second absolute particle size distribution - first absolute particle size distribution ) / first absolute particle size distribution ] * 100 \%$$

Referring now to the detail of FIG. 4, in some embodiments, the qualification method 200 may further comprise a step of:
calculating the first absolute particle size distribution by the first particle size distribution and the first signal peak intensity measuring from the photoresist developer solution, and the second absolute particle size distribution by the second particle size distribution and the second signal peak intensity measuring from the used photoresist developer solution 213B.

Continuing to FIG. 4, in some embodiments, the qualification method 200 may further comprise a step of:
calculating the change of the particle size distribution by the first absolute particle size distribution and the second absolute particle size distribution 214B.

Accordingly, in some embodiments of the qualification method, the first specified limit may be above 9%. In still another embodiment, the first specified limit value may be varied from 9% to 100% and preferably be varied from 9% to 50%. While the change of the absolute zeta potential value is within the range of the first specified limit, it can be reasonably judged that there are much more dirt colloids adsorbing back to the developing substrate and also other solid boundaries in the chemical developing process tank. Therefore, it can be anticipated that unwanted back adsorptions will possibly lead to substrate development failure.

Accordingly, in some embodiments of the qualification method, the second specified limit may be above 20%. In still another embodiment, the second specified limit may be varied from 20% to 300%, and preferably from 20% to 100%. While the change of the particle size distribution is over the defined second specified limit, it can be reasonably expected that the efficiency of batch photoresist development may be decreased. For example, many more dirt colloids are absorbed back into the developing substrate and other solid boundaries in the chemical developing process tank. Therefore, it can be anticipated that unwanted back adsorptions will possibly lead to substrate development failure.

Therefore, in some embodiments, while the change of the particle size distribution is above the second specified limit and/or the change of the absolute zeta potential value is above the first specified limit, the batch photoresist development may be either draining out the used photoresist developer solution, shutting down the batch photoresist development, or adding more photoresist developer solutions to make the batch photoresist development operate well, and in this situation, it may significantly reduce utilization of process water, so that the automatic operation can be expected.

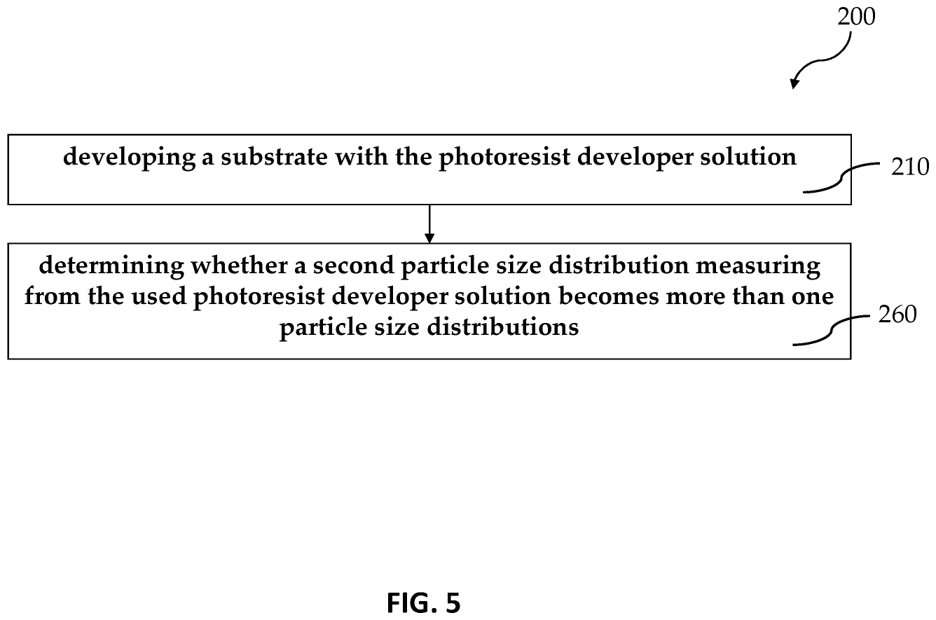

Referring to FIG. 5, in some embodiments, the qualification method 200 may further comprise a step of:
determining whether the second particle size distribution measured from the used photoresist developer solution becomes more than one particle size distribution 260.

Accordingly, the second particle size distribution may become more than one particle size distributions. It should be noted that, in some embodiments, when the particle size distribution starts to separate as two distributions, the photoresist development process may fail due to dirt colloids adsorbing back to the developed substrate and also other solid boundaries generated in the chemical developing process tank.

According to FIGS. 2-5, in some embodiments, the qualification method 200 may further comprise a step of:
recycling the used photoresist developer solution to the next batch photoresist development 270.

Alternatively, in some embodiments, the qualification method 200 may further comprise a step of:
adding more photoresist developer solutions in the chemical developing process tank 280.

In still another embodiment, referring to FIG. 5, the qualification method 200 may further comprise a step of:
shutting down the batch photoresist development while the second particle size distribution becomes more than one particle size distribution 261.

In still some embodiments, the photoresist developer solution may comprise:
0 wt %˜99.5 wt % Water;
0.5 wt %˜1.5 wt % Alkaline chemical mixtures comprising tetra-methyl ammonium hydroxide, tetra-butyl ammonium hydroxide, potassium carbonates, sodium carbonates, and ammonium carbonates;
0.001 wt %˜0.5 wt % dispersing agents;
0.001 wt %˜0.5 wt % wetting agents;
0.001 wt %˜0.5 wt % antifoaming agents; and
0.001 wt %˜0.5 wt % de-foaming agents.

Accordingly, in this way, in some embodiments, water is a necessary medium to disperse all the developing ingredients and to take out the unwanted photoresists and residual materials from the resist coating substrate. De-ionized water is preferred.

In still some embodiments, the Alkaline chemical mixtures may be adopted to keep the solutions pH value in an appropriate working range and to provide the basic hydroxide ions OH⁻ or carbonate ions CO3²⁻. The hydroxide ions OH⁻ or the carbonate ions CO3²³¹ may promote unwanted photoresist polymers and residual materials ionization and then the unwanted photoresist polymers and residual materials may be aggregated to form colloids with electric double layers suspending in the photoresist developer solution.

In still another embodiment, the dispersing agents are one of the most important keys to control the mentioned polymers/materials' colloids with their stability and interphase equilibrium with the photoresist developer solution. The invention discloses the details of key ingredients hereinafter. The dispersing agents may contain carbon-carbon triple bond, carbon-carbon double bond, and aromatic structures with hydrophilic-lipophilic balance (HLB) values ranging from 4 to 18, which have surprisingly active to manage photoresist components forming colloids. The dispersing agents containing triple bonds may be much preferred.

In still another embodiment, the dispersing agents having triple bonds may be selected from a group consisting of 2,4,7,9-Tetramethyl-5-decyne-4,7-diol ethoxylates with HLB value ranging from 4 to 18 and more preferably from 8 to 15, 1,4-Butynediol ethoxylates with HLB value ranging from 4 to 18 and more preferably from 8 to 15, 2,4,7,9-Tetramethyl-5-decyne-4,7-diol ethoxylates or proxylates with HLB value ranging from 4 to 18 and more preferably from 8 to 15, 1,4-Butynediol ethoxylates or proxylates with HLB value ranging from 4 to 18 and more preferably from 8 to 15 and a combination thereof.

In still another embodiment, the dispersing agents having double bonds having aromatic structure are selected from a group consisting of bio-based Cardanol ethoxylates with HLB value ranging from 3 to 18 and more preferably from 8 to 15, nonyl phenol ethoxylates with HLB value ranging from 3 to 18 and more preferably from 8 to 15, alkyl phenol ethoxylates with HLB value ranging from 3 to 18 and more preferably from 8 to 15, 4-cumylphenol ethoxylates with HLB value ranging from 3 to 18 and more preferably from 8 to 15 and a combination thereof.

The wetting agents may promote the dispersing agent's performance in the photoresist developing process and further prolong the working lifetime of the dispersing agents. The wetting agents are selected from a group consisting of mono-ethylene glycol, di-ethylene glycol, tri-ethylene glycol, polyethylene glycol with molecular weight from 100 to 600, ethoxylated butyl ethers, ethylene carbonate, propylene carbonate, C8-10 fatty alcohol 2-3 moles ethylene oxide (EO) ethoxylates, non-ionic chemicals comprising below 11 carbon chains, ethylene oxide adducts with HLB ranging from 4 to 10, propylene oxide adducts with HLB ranging from 4 to 10, linear secondary alcohol ethoxylates with HLB ranging from 4 to 10, linear secondary alcohol proxylates with HLB ranging from 4 to 10, branched secondary alcohol ethoxylates with HLB ranging from 4 to 10, branched secondary alcohol proxylates with HLB ranging from 4 to 10 and a combination thereof.

It is important to appreciate that since there are possibly some portions of dispersing agents or auxiliary wetting agents distributed near air-water interface, bubble generation is not evitable. The excess of bubble foam may cause the overflow of the chemical developing process tank, and the batch photoresist development may potentially shut down.

In still some embodiments, the combination of antifoaming agents and de-foaming agents works to manage foam. the antifoaming agents are selected from a group consisting of primary linear C12-14 fatty alcohol 2-3 moles ethylene oxide (EO) ethoxylates, isotridecanol 2-3 moles EO ethoxylates, isodecyl alcohol 2-3 moles EO ethoxylates, oleyl alcohol 2-3 moles EO ethoxylates, C16-18 fatty alcohol 2-3 moles ethylene oxide (EO) ethoxylates, triblock copolymers of ethylene oxide and propylene oxide, C8-14 alcohol ethylene oxide/propylene oxide block copolymers, C8-14 alcohol ethylene oxide/propylene oxide random copolymers, primary linear C12-14 fatty alcohol ethylene oxide/propylene oxide block copolymers, primary linear C12-14 fatty alcohol ethylene oxide/propylene oxide random copolymers, isotridecanol ethylene oxide/propylene oxide block copolymers, iso-tridecanol ethylene oxide/propylene oxide random copolymers, oleyl alcohol ethylene oxide/propylene oxide block copolymers, oleyl alcohol ethylene oxide propylene oxide random copolymers, C16-18 fatty alcohol ethylene oxide/propylene oxide block copolymers, polypropylene glycols with molecular weight up to 2000 and a combination thereof.

In still some embodiment, the de-foaming agents are selected from a group consisting of white mineral oil, palm kernel oil, palm sterin oil, horse oil, shea butter, wax, other mineral oil, and a combination thereof.

According to the photoresist developer solution mentioned above, the composition of the photoresist developer solution may be applied in the photoresist developing process and the qualification method for determining dump time intervals in the batch photoresist development. The composition of the photoresist developer solution may significantly extend the aqueous-based photoresist developer solutions working lifetime even though it already contains unwanted photoresists and other residual chemicals (e.g., the used photoresist developer solution). The used photoresist developer solution can also be viewed as concentrated colloidal suspensions. The disclosed composition of the photoresist developer solution can help to form stable colloidal mixtures with acceptable particle size distribution. The stable colloidal mixtures can prolong the working time of the photoresist developer solution and prevent forming of larger aggregates to re-adsorb or sediment on any solid boundary in developing process mechanical units to reasonably anticipate the reduction of chemicals used, chemical waste, and the utilization of process water, namely potentially low carbon emission.

It should be noted that regardless of the type of photoresists chosen by development units, the main root cause of the development process unit shutdown is materials or larger particle-size dirt colloids back adsorbing on the developed substrates. Normally, people use eyes to determine colloids already aggregating after colloidal developing solution suspensions become more unstable than fresh ones. Therefore, after the photoresist developer solution mentioned above is used, the concentrated unwanted materials such as photo-initiators (PI), residuals containing aromatic structure resins, and other small organic and inorganic chemicals within the used photoresist developer solution may be more stable.

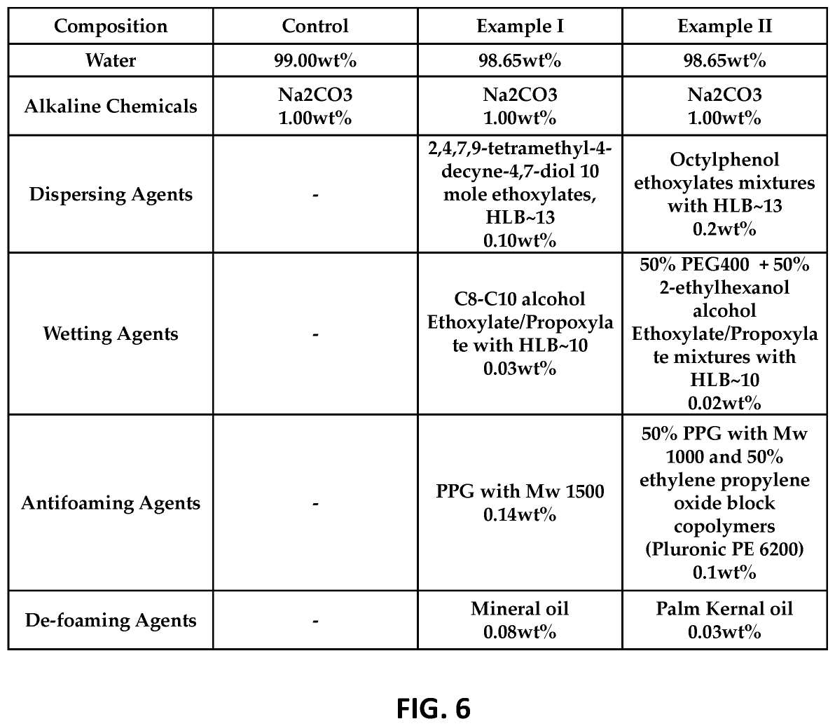

FIG. 6 generally depicts the composition of the photoresist developer solution practical batch photoresist development process units according to an aspect of the embodiments. The practical batch photoresist development process units may vary with development requirements. Only one or two and even above two cascaded chemical developing process tanks together with residual resists cleaning washing tanks may be utilized. The photoresist development process is in a continuous run, conveying several substrates containing both exposure and non-exposure photoresists from the starting point of the chemical developing process tanks to the end of the tanks where the resident time of chemical development can be viewed as the path of the substrate conveying divided by conveying rate. Usually, in the operation line, treated quantities of the substrates are viewed as the process running time of the development tank, i.e., 500, 1000, 2000, 3000, and 5000 sets. Another operation is determined by labor shift, i.e., 8 Hrs, 16 Hrs, 24 Hrs, and the like. Photoresist development conveying line can also be designed to send two or more substrates in parallel passing through chemical developing process tanks.

As shown in further detail in FIG. 6, the substrate in the photoresist development process may comprise Copper, Taiwan, which is coated with an Eternal 115T dry film photoresist provided by Eternal Group, Taiwan. The photoresist developer solution of the control group includes 1 wt % sodium carbonate solutions, and Example I and Example II comprise the composition of the photoresist developer solution representing the current invention.

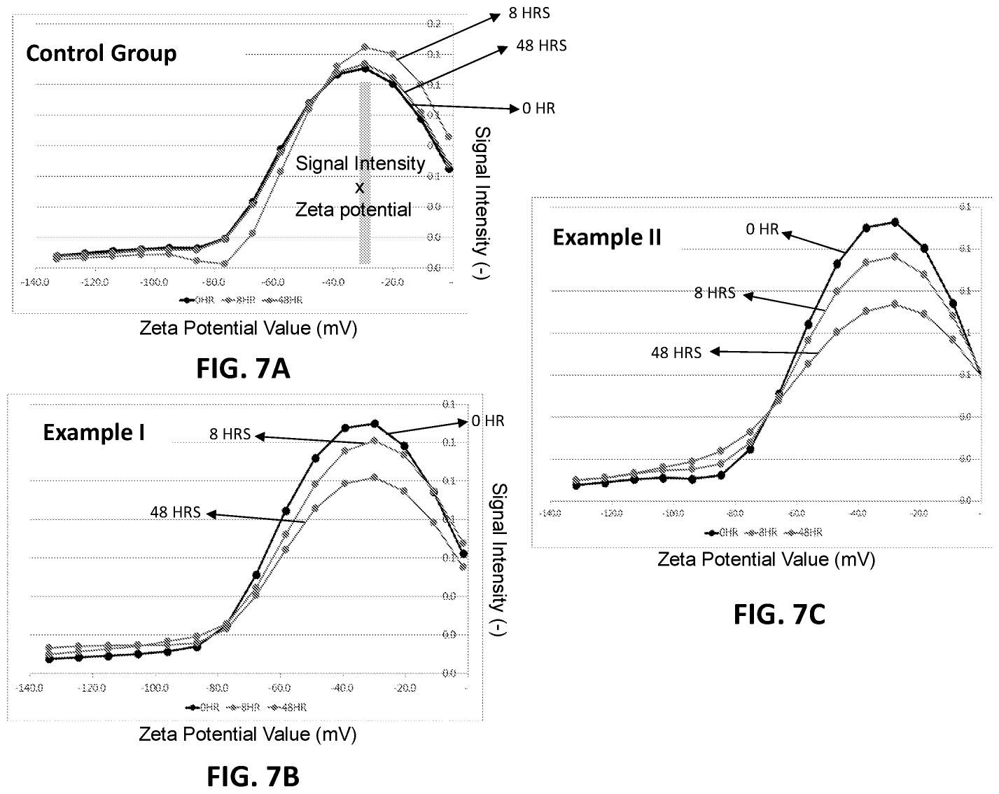

FIGS. 7A to 7C generally depict analytical results measured by the analytical instrument 106 (a zeta potential and particle size analyzer) according to an aspect of the embodiments.

According to FIGS. 7A to 7C, the substrate in the photoresist development process may comprise Copper, which is coated with an Eternal 115T dry film photoresist provided by Eternal Group, Taiwan. The composition of the control group, Example I, and Example II are shown in FIG. 6.

Referring to FIGS. 7A to 7C, the signal intensity and the zeta potential value are measured by the analytical instrument 106 (a zeta potential and particle size analyzer), and data results are plotted to record as FIGS. 7A to 7C. As shown in FIGS. 7A to 7C, the zeta potential value may range from 0 to −140 mV, and the operation is determined by labor shift, i.e., 0 Hrs, 8 Hrs, 48 Hrs. The composition of the control group, Example I, and Example II are shown in FIG. 6.

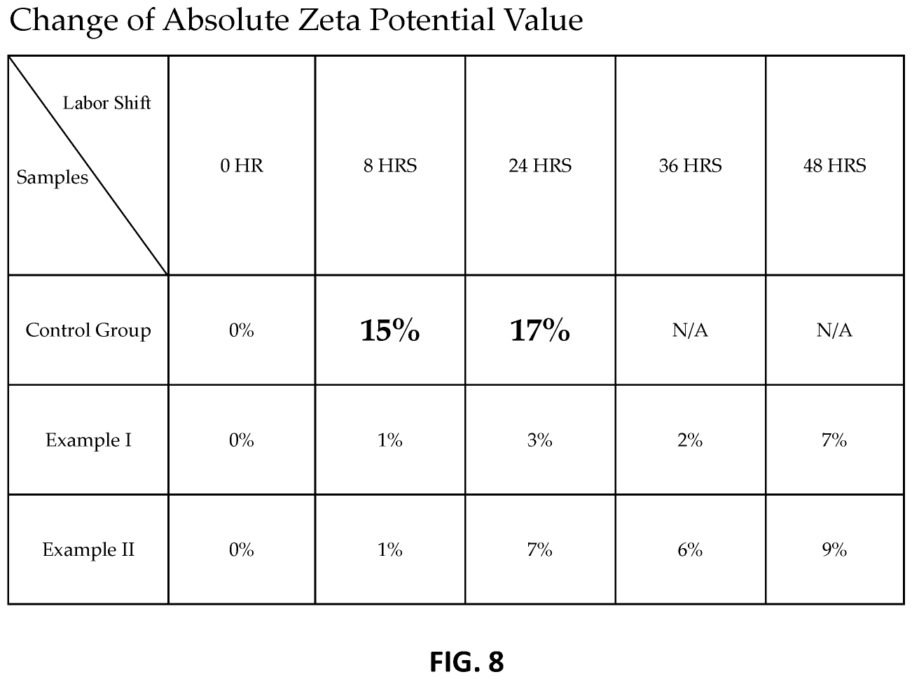

FIG. 8 generally depicts the change of the absolute zeta potential value for the control group, Example I, and Example II according to an aspect of the embodiments.

According to FIG. 8, the substrate in the photoresist development process may comprise Copper provided by Chang Chun Group, Taiwan, which is coated with an Eternal 1115T dry film photoresist provided by Eternal Group, Taiwan. The composition of the control group, Example I, and Example II are shown in FIG. 6.

Referring to FIG. 8, the signal intensity is calculated from 0 to −128 mV, and the labor shift is calculated from 0 Hrs, 8 Hrs, 24 Hrs, 36 Hrs, and 48 Hrs. Accordingly, in the control group, in the operation of labor shift of 8 Hrs, the change of the absolute zeta potential value starts to be within the first specified limit, 9% to 50%, and the change of the absolute zeta potential value at the labor shift of 8 Hrs is 15%. After 8 Hrs, the change of the absolute zeta potential value is 17% at 24 Hrs. In such a situation, the photoresist development process may shut down for cleaning or feeding fresh photoresist developer solutions.

Similarly, in Example I and in Example II, until the operation of the labor shift is 48 Hrs, in Example I, the change of the absolute zeta potential value is still not within the first specified limit, 9% to 50%, wherein in Example II, the change of the absolute zeta potential value is 9%. Therefore, while the composition of the photoresist developer solution is in Example I and Example II, the photoresist development process may shut down for cleaning or feeding fresh photoresist developer solution after 48 Hrs.

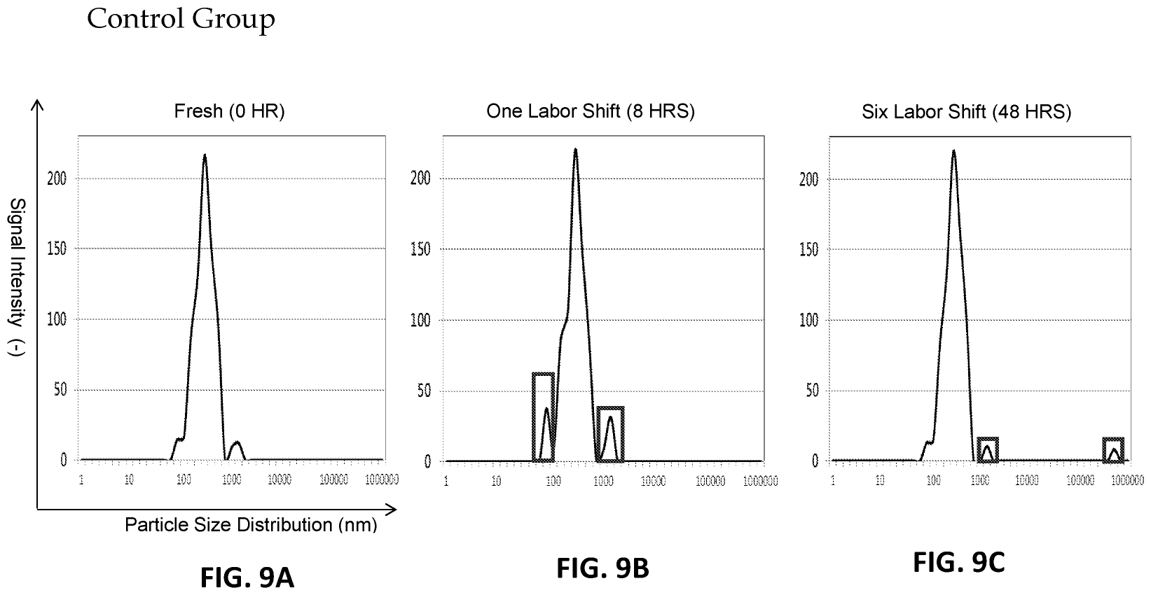

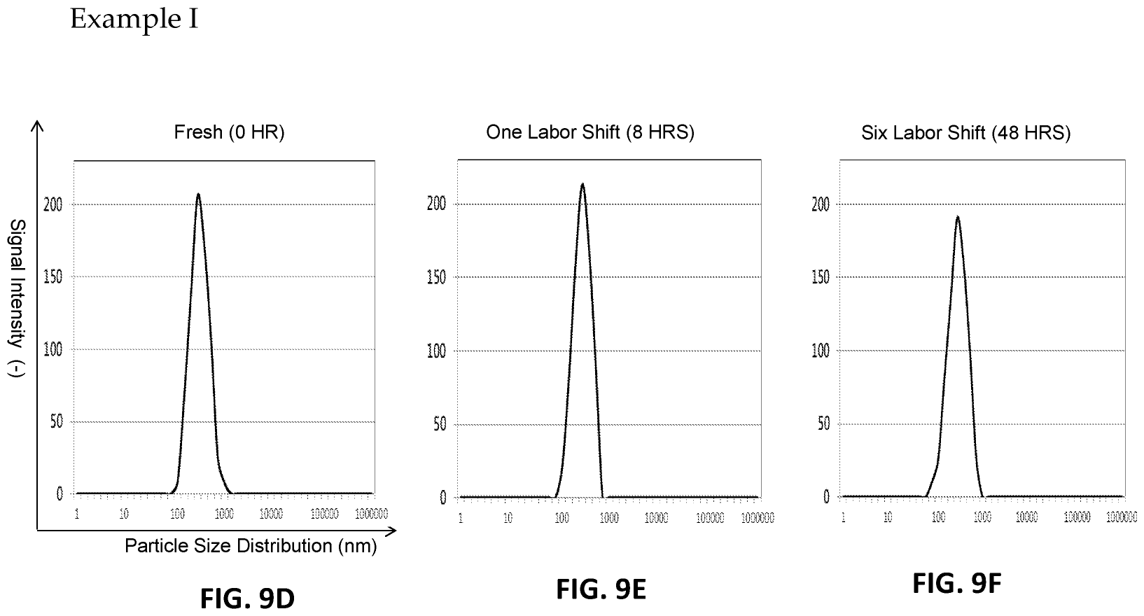

FIGS. 9A to 9F generally depict analytical results measured by the analytical instrument 106 (a zeta potential and particle size analyzer) according to an aspect of the embodiments. The signal intensity and the particle size distribution are measured by the analytical instrument 106 (a zeta potential and particle size analyzer), and data results are plotted to record as FIGS. 9A to 9F. As shown in FIGS. 9A to 9F, the particle size distribution is measured from 0 nm to 1000000 nm, and the operation is determined by labor shift, i.e., 0 Hrs, 8 Hrs, and 48 Hrs. The substrate in the photoresist development process may comprise Copper, which is coated with an Eternal 115T dry film photoresist provided by Eternal Group, Taiwan. The composition of the control group and Example I (Formulation I) are shown in FIG. 6.

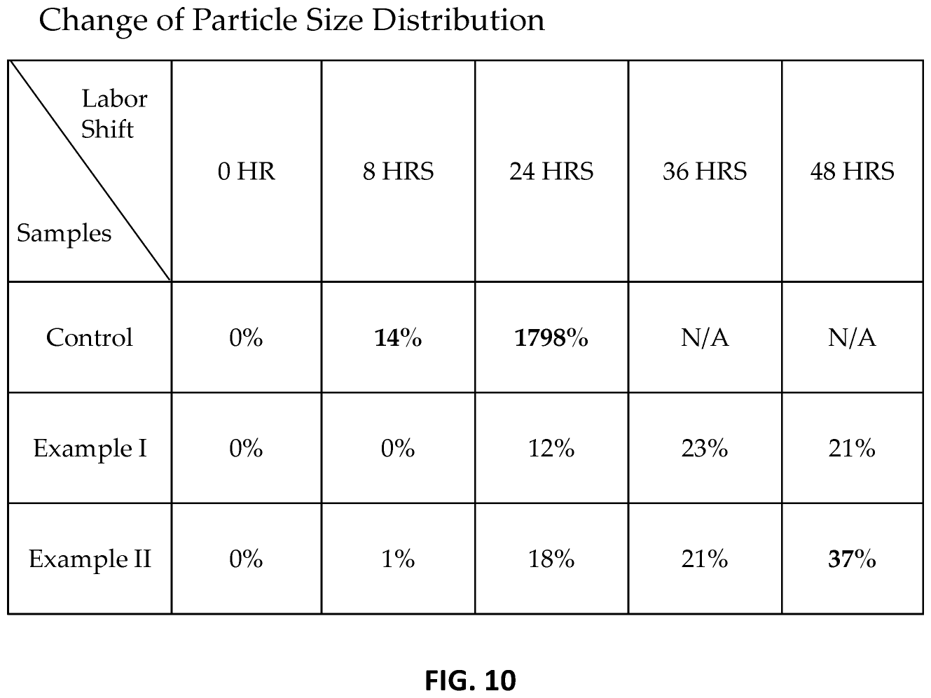

FIG. 10 generally depicts the change of the particle size distribution for the control group, Example I, and Example II according to an aspect of the embodiments.

Referring to FIG. 10, the substrate in the photoresist development process may comprise Copper, which is coated with an Eternal 115T dry film photoresist provided by Eternal Group, Taiwan. The composition of the control group, Example I, and Example II are shown in FIG. 6.

Referring to FIG. 10, the particle size distribution is measured from 0 nm to 1000000 nm, and the labor shift is calculated from 0 Hrs, 8 Hrs, 24 Hrs, 36 Hrs, and 48 Hrs. Accordingly, in the control group, in the operation of labor shift of 8 Hrs, the change of the particle size distribution starts to approach the second specified limit, 30% to 100%, and the change of the particle size distribution at the labor shift of 8 Hrs is 14%. After 8 Hrs, the change of the particle size distribution is 1798% at 24 Hrs. In such a situation, the photoresist development process may shut down for cleaning or feeding fresh photoresist developer solutions.

Similarly, in Example I and in Example II, until the operation of the labor shift is 48 Hrs, in Example I, the change of the particle size distribution is 21% which is not within the second specified limit, 30% to 100%, wherein in Example II, the change of the particle size distribution is 37%. Therefore, while the composition of the photoresist developer solution is in Example I and Example II, the photoresist development process may shut down for cleaning or feeding fresh photoresist developer solution after or at 48 Hrs.

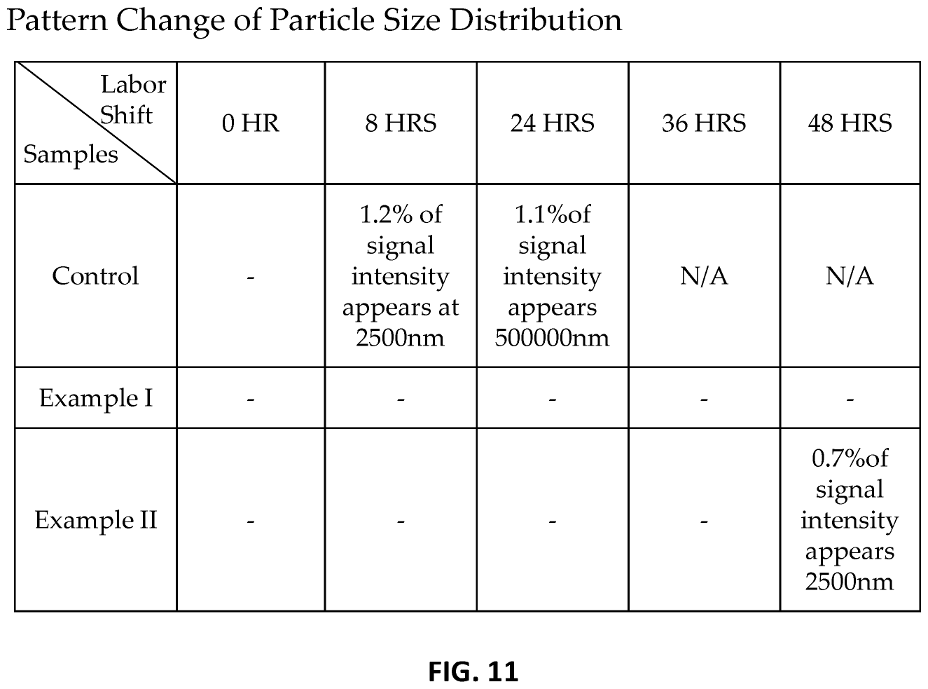

FIG. 11 depicts a pattern change of the particle size distribution for the control group, Example I, and Example II according to an aspect of the embodiments.

Referring to FIG. 11, the particle size distribution is measured from 0 nm to 1000000 nm, and the labor shift is calculated from 0 Hrs, 8 Hrs, 24 Hrs, 36 Hrs, and 48 Hrs. The substrate in the photoresist development process may comprise copper, which is coated with an Eternal 115T dry film photoresist provided by Eternal Group, Taiwan. The composition of the control group, Example I, and Example II are shown in FIG. 6. Also, referring back to FIG. 9A to FIG. 9F, the corresponding analytical results measured by the analytical instrument 106 can be used to illustrate FIG. 11.

Continuing to FIG. 11, in the control group, in the operation of labor shift of 8 Hrs, the first separated particle size distribution shows as 1.2% of signal intensity appears at 2500 nm. After 8 Hrs, the second separated particle size distribution as 1.1% of signal intensity appears at 500000 nm at 24 Hrs (see FIGS. 9A to 9C). In such a situation, the photoresist development process may shut down for cleaning or feeding fresh photoresist developer solutions.

Similarly, referring to FIG. 11, in Example I and in Example II, until the operation of the labor shift is 48 Hrs, in Example I, there is no separated particle size distribution (also shown in FIGS. 9D to 9F), wherein in Example II, a first separated particle size distribution as 0.7% of signal intensity appears at 2500 nm, and in such a situation, the photoresist development process may shut down for cleaning or feeding fresh photoresist developer solution after or at 48 Hrs.

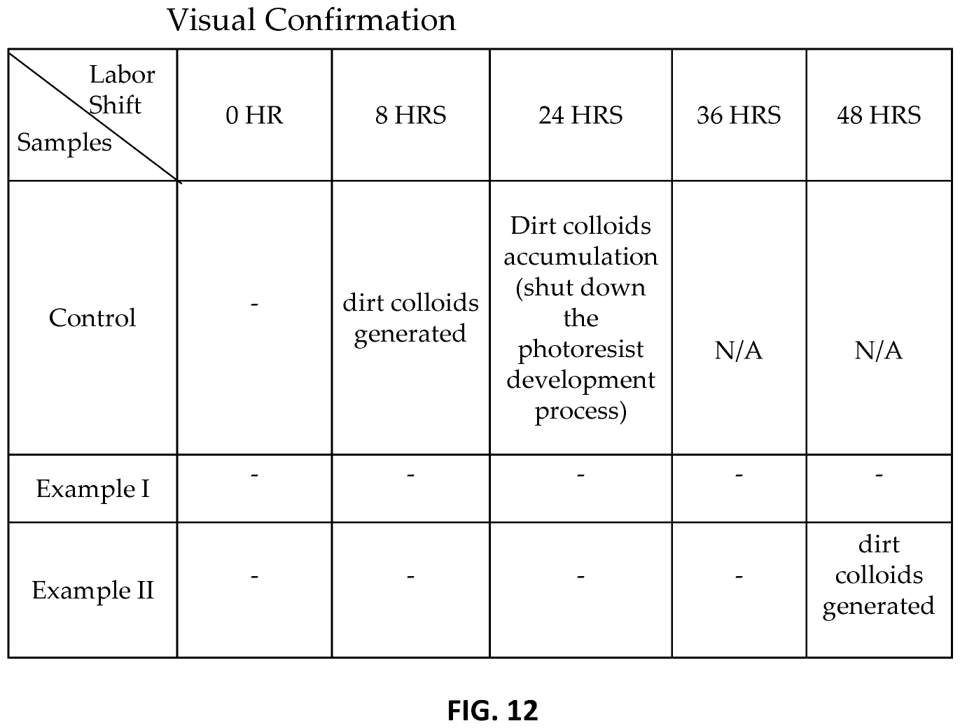

FIG. 12 shows a condition of dirt colloids measured by a visual confirmation according to an aspect of the embodiment. The substrate in the photoresist development process may comprise copper, which is coated with an Eternal 115T dry film photoresist provided by Eternal Group, Taiwan. The composition of the control group, Example I, and Example II are shown in FIG. 6. The labor shift is measured from 0 Hrs, 8 Hrs, 24 Hrs, 36 Hrs, and 48 Hrs.

Referring to FIG. 12, in the control group, in the operation of labor shift of 8 Hrs., the dirt colloids start to generate. After 8 Hrs, the dirt colloids accumulate at 24 Hrs. In such a situation, the photoresist development process may shut down for cleaning or feeding fresh photoresist developer solutions.

Similarly, in Example I and in Example II, until the operation of the labor shift is 48 Hrs., in Example I, no dirt colloids are generated, wherein in Example II, the dirt colloids are generated at 48 Hrs., and in such a situation, the photoresist development process may shut down for cleaning or feeding fresh photoresist developer solution after or at 48 Hrs.

According to above mentioned analytical results measured by the analytical instrument 106, the composition of the photoresist developer solution of the present invention could efficiently prolong the dump time interval for the photoresist developer solution during the photoresist development process and further successfully reuse or recycle the used photoresist developer solution.

Many alterations and modifications may be made by those having ordinary skill in the art without departing from the spirit and scope of the disclosed embodiments. Therefore, it must be understood that the illustrated embodiments have been set forth only for the purposes of example and that it should not be taken as limiting the embodiments as defined by the following claims. For example, notwithstanding the fact that the elements of a claim are set forth below in a certain combination, it must be expressly understood that the embodiment includes other combinations of fewer, more, or different elements, which are disclosed herein even when not initially claimed in such combinations.

Thus, specific embodiments and applications of photoresist developer solutions containing low foam dispersing compositions and quantification methods have been disclosed. It should be apparent, however, to those skilled in the art that many more modifications besides those already described are possible without departing from the disclosed concepts herein. The disclosed embodiments, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Insubstantial changes from the claimed subject matter as viewed by a person with ordinary skill in the art, now known or later devised, are expressly contemplated as equivalent within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be substituted and also what essentially incorporates the essential idea of the embodiments. In addition, where the specification and claims refer to at least one of something selected from the group consisting of A, B, C . . . and N, the text should be interpreted as requiring at least one element from the group which includes N, not A plus N, or B plus N, etc.

The words used in this specification to describe the various embodiments are to be understood not only in the sense of their commonly defined meanings but to include by special definition in this specification structure, material or acts beyond the scope of the commonly defined meanings. Thus, if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

What is claimed is:

1. A qualification method for determining a dump time interval using a photoresist developer solution in a batch photoresist development, comprising:
developing a substrate with the photoresist developer solution;
determining whether a change of an absolute zeta potential value between the photoresist developer solution and a used photoresist developer solution exceeds a first specified limit; and
determining whether a change of a particle size distribution between the photoresist developer solution and the used photoresist developer solution exceeds a second specified limit; wherein
if the change of the absolute zeta potential value is within the first specified limit, dumping the used photoresist developer solution; and
if the change in the particle size distribution is within the second specified limit, dumping the used photoresist developer solution.

2. The qualification method of claim 1, wherein the first specified limit is above 9%.

3. The qualification method of claim 1, wherein the second specified limit is above 20%.

4. The qualification method of claim 1, wherein the photoresist developer solution comprises:
0 wt %˜99.5 wt % Water;
0.5 wt %˜1.5 wt % Alkaline chemical mixtures comprising tetra-methyl ammonium hydroxide, tetra-butyl ammonium hydroxide, potassium carbonates, sodium carbonates, and ammonium carbonates;
0.001 wt %˜0.5 wt % dispersing agents;
0.001 wt %˜0.5 wt % wetting agents;
0.001 wt %˜0.5 wt % antifoaming agents; and
0.001 wt %˜0.5 wt % de-foaming agents.

5. The qualification method of claim 1, further comprising a step of:
calculating a first absolute zeta potential value by a first zeta potential value and a first signal peak intensity measuring from the photoresist developer solution, and a second absolute zeta potential value by a second zeta potential value and a second signal peak intensity measuring from the used photoresist developer solution.

6. The qualification method of claim 5, further comprising a step of:
calculating the change of the absolute zeta potential value by the first absolute zeta potential value and the second absolute zeta potential value.

7. The qualification method of claim 1, further comprising a step of:
calculating a first absolute particle size distribution by a first signal peak intensity and a first particle size distribution measuring from the photoresist developer solution, and a second absolute particle size distribution by a second particle size distribution and a second signal peak intensity measuring from the used photoresist developer solution.

8. The qualification method of claim 7, further comprising a step of:
calculating the change of the particle size distribution by the first absolute particle size distribution and the second absolute particle size distribution.

9. The qualification method of claim 1, further comprising a step of:
recycling the used photoresist developer solution to a next batch photoresist development.

10. The qualification method of claim 1, further comprising a step of:
determining whether a second particle size distribution measuring from the used photoresist developer solution becomes more than one particle size distribution; and
shutting down the batch photoresist development.

11. The qualification method of claim 1, further comprising a step of:
acquiring a first signal peak intensity of the photoresist developer solution and a second signal peak intensity of the used photoresist developer solution, using the zeta potential and particle size analyzer; and
acquiring a first particle size distribution of the photoresist developer solution and a second particle size distribution of the used photoresist developer solution, using a zeta potential and particle size analyzer.

12. The qualification method of claim 1, further comprising a step of:
acquiring a first signal peak intensity of the photoresist developer solution and a second signal peak intensity of the used photoresist developer solution, using the zeta potential and particle size analyzer; and
acquiring a first zeta potential value of the photoresist developer solution and a second zeta potential value of the used photoresist developer solution, using a zeta potential and particle size analyzer.

13. A photoresist developer solution, comprising:
0 wt %˜99.5 wt % Water;
0.5 wt %˜1.5 wt % Alkaline chemical mixtures comprising tetra-methyl ammonium hydroxide, tetra-butyl ammonium hydroxide, potassium carbonates, sodium carbonates, and ammonium carbonates;
0.001 wt %˜0.5 wt % dispersing agents;
0.001 wt %˜0.5 wt % wetting agents;
0.001 wt %˜0.5 wt % antifoaming agents; and
0.001 wt %˜0.5 wt % de-foaming agents.

14. The composition of claim 13, wherein the dispersing agents comprises carbon-carbon triple bond with hydrophilic-lipophilic balance (HLB) value ranging from 4 to 18.

15. The composition of claim 13, wherein the dispersing agents comprises carbon-carbon double bond having aromatic structures with hydrophilic-lipophilic balance (HLB) value ranging from 3 to 18.

16. The composition of claim 13, wherein the wetting agents are selected from a group consisting of mono-ethylene glycol, di-ethylene glycol, tri-ethylene glycol, polyethylene glycol with molecular weight from 100 to 600, ethoxylated butyl ethers, ethylene carbonate, propylene carbonate, C8-10 fatty alcohol 2-3 moles ethylene oxide (EO) ethoxylates, non-ionic chemicals comprising below 11 carbon chains, ethylene oxide adducts with HLB ranging from 4 to 10, propylene oxide adducts with HLB ranging from 4 to 10, linear secondary alcohol ethoxylates with HLB ranging from 4 to 10, linear secondary alcohol proxylates with HLB ranging from 4 to 10, branched secondary alcohol ethoxylates with HLB ranging from 4 to 10, branched secondary alcohol proxylates with HLB ranging from 4 to 10 and a combination thereof.

17. The composition of claim 13, wherein the antifoaming agents are selected from a group consisting of primary linear C12-14 fatty alcohol 2-3 moles ethylene oxide (EO) ethoxylates, isotridecanol 2-3 moles EO ethoxylates, isodecyl alcohol 2-3 moles EO ethoxylates, oleyl alcohol 2-3 moles EO ethoxylates, C16-18 fatty alcohol 2-3 moles ethylene oxide (EO) ethoxylates, triblock copolymers of ethylene oxide and propylene oxide, C8-14 alcohol ethylene oxide/propylene oxide block copolymers, C8-14 alcohol ethylene oxide/propylene oxide random copolymers, primary linear C12-14 fatty alcohol ethylene oxide/propylene oxide block copolymers, primary linear C12-14 fatty alcohol ethylene oxide/propylene oxide random copolymers, isotridecanol ethylene oxide/propylene oxide block copolymers, iso-tridecanol ethylene oxide/propylene oxide random copolymers, oleyl alcohol ethylene oxide/propylene oxide block copolymers, oleyl alcohol ethylene oxide propylene oxide random copolymers, C16-18 fatty alcohol ethylene oxide/propylene oxide block copolymers, polypropylene glycols with molecular weight up to 2000 and a combination thereof.

18. The composition of claim 13, wherein the de-foaming agents are selected from a group consisting of white mineral oil, palm kernel oil, palm sterin oil, horse oil, shea butter, wax, other mineral oil, and a combination thereof.

19. The composition of claim 13, wherein the dispersing agents are selected from a group consisting of 2,4,7,9-Tetramethyl-5-decyne-4,7-diol ethoxylates with HLB value ranging from 4 to 18, 1,4-Butynediol ethoxylates with HLB value ranging from 4 to 18, 2,4,7,9-Tetramethyl-5-decyne-4,7-diol ethoxylates or proxylates with HLB value ranging from 4 to 18, 1,4-Butynediol ethoxylates or proxylates with HLB value ranging from 4 to 18 and a combination thereof.

20. The composition of claim 13, wherein the dispersing agents are selected from a group consisting of bio-based Cardanol ethoxylates with HLB value ranging from 3 to 18, nonyl phenol ethoxylates with HLB value ranging from 3 to 18, alkyl phenol ethoxylates with HLB value ranging from 3 to 18, 4-cumylphenol ethoxylates with HLB value ranging from 3 to 18 and a combination thereof.
